(19) United States
(12) Patent Application Publication
(10) Pub. No.: US 2015/0171304 A1
(43) Pub. Date: Jun. 18, 2015

(54) Thermoelectric Elements Including of Axially Dependent Material Properties

(71) Applicant: Evident Technologies, Troy, NY (US)

(72) Inventors: Clinton T. Ballinger, Burnt Hills, NY (US); Bed Poudel, Newtonville, MA (US)

(21) Appl. No.: 14/573,399

(22) Filed: Dec. 17, 2014

Related U.S. Application Data
(60) Provisional application No. 61/917,006, filed on Dec. 17, 2013.

(51) Int. Cl. H01L 35/34; H01L 35/02

(52) U.S. Cl. CPC H01L 35/34; H01L 35/02

(57) ABSTRACT

Disclosed herein are a thermoelectric device produced by a method utilizing consolidation techniques and a method of producing a thermoelectric device. The method can include layering a first powdered conductor in a die, layering a first powdered semiconductor material on the first powdered conductor layer, layering a second powdered conductor in the die, and consolidating each of the layers.

### CROSS-REFERENCE TO RELATED APPLICATIONS

This application claims the benefit of co-pending U.S. Provisional Application Ser. No. 61/917,006, filed 17 Dec. 2013, which is hereby incorporated by reference herein.

### FIELD OF THE INVENTION

Embodiments of the present invention relate generally to compositions of materials capable of enhancing the performance of a thermoelectric device.

### BACKGROUND OF THE INVENTION

Thermoelectric devices are used to create a temperature gradient when an electric current is passed through the appropriate p/n material junction. Conversely, a current is produced when thermoelectric elements are exposed to a temperature gradient. In either mode of operation, there is a temperature gradient across the thermoelectric element. Materials often behave differently at different temperatures.

The underlying reason for these temperature dependent performance changes are due to the fact that the basic properties of the material are inherently temperature dependent. For example, thermal and electrical conductivities change as a function of temperature. One of the key considerations in designing a thermoelectric device is to understand this changing thermal and electrical performance as a function of temperature. Typically, a lower thermal conductivity will lead to a higher performing thermoelectric element. However, thermal conductivity is usually tied directly to electrical conductivity. While a material may have a low thermal conductivity, it is unlikely to have a high electrical conductivity because thermal conductivity and electrical conductivity are positively correlated.

Hence, there is a balance between thermal and electrical properties that maximize the performance of a material. Thermoelectric materials are typically rated by their figure of merit, ZT, shown in the following formula:

$$ZT = \frac{σ {S}^{2} T}{λ} .$$

This ZT is well known in the art and is a function of the square of the Seebeck coefficient, S, multiplied by the electrical conductivity (σ) and divided by the thermal conductivity (λ), where the entire quotient is multiplied by the absolute temperature (T).

### BRIEF DESCRIPTION OF THE INVENTION

Embodiments of the invention disclosed herein may include a method of producing a thermoelectric device, the method comprising: layering a first powdered conductor in a die; layering a first powdered semiconductor material on the first powdered conductor layer; layering a second powdered conductor in the die; and consolidating each of the layers.

Embodiments of the invention may also include a thermoelectric device produced by a method utilizing consolidation techniques, the method comprising: layering a first powdered conductor in a die; layering a first powdered semiconductor material on the first powdered conductor layer; layering a second powdered conductor in the die; and consolidating each of the layers.

### BRIEF DESCRIPTION OF THE FIGURES

FIG. 1 illustrates a flow chart of a method according to some embodiments of the present invention.

FIG. 2 illustrates a layered material according to some embodiments of the present invention.

FIG. 3 illustrates a layered material including a second semiconductor layer according to some embodiments of the present invention.

FIG. 4 illustrates a layered material including variations in initial particle grain size according to some embodiments of the present invention.

FIG. 5 illustrates a layered material including diffusion barriers according to some embodiments of the present invention.

### DETAILED DESCRIPTION OF THE INVENTION

The present invention discloses the use of axially dependent material properties (e.g., temperature dependent as the temperature across the material changes axially) to maximize the performance of a thermoelectric element. As disclosed above, there is a temperature gradient across most thermoelectric elements. Often, materials will behave differently at different temperatures. For example, LEDs and solar cells are not as efficient when they are at elevated temperatures. Some materials like skutterudites, however, perform better at temperatures above 200 C.

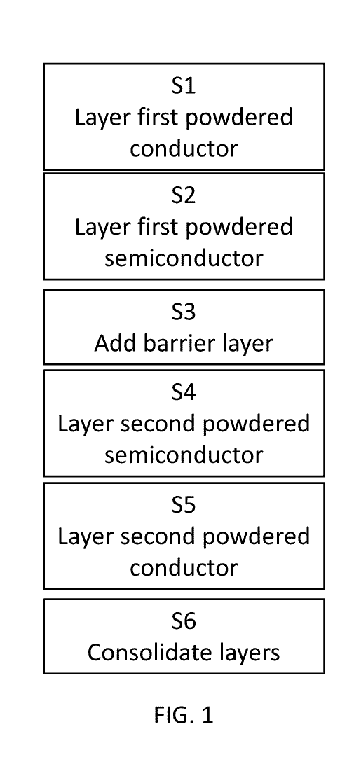

In some embodiments, a method of producing a thermoelectric device, as illustrated in FIG. 1, is presented. It should be understood that these steps are presented in an order only for illustration, and that the order of the steps can be altered within the scope of the invention. In S1, a first powdered conductor is layered in a die. In S2, a first powdered semiconductor material is layered on the first powdered conductor layer. In some embodiments, in S3, at least one powdered diffusion barrier layer may be added between any of the disclosed layers. For instance, a diffusion barrier layer can be added between two layers or all of the disclosed layers, or any combination. In some embodiments, S4 includes layering a second powdered semiconductor layer between the first powdered semiconductor layer and one of the first powdered conductor layer or the second powdered conductor. S5 includes layering a second powdered conductor in the die. S6 includes consolidating the layers. Specific examples and details of these steps are disclosed in further detail below.

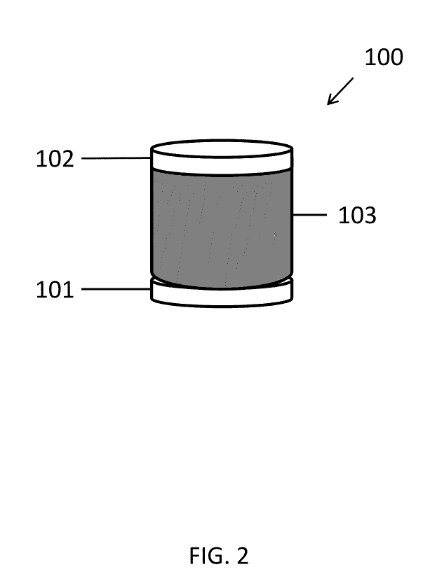

In some embodiments, as illustrated in FIG. 2, a thermoelectric device 100 may be produced by consolidating a set of layers, described above, together with a first conductor layer 101 on the bottom and/or a second powdered conductor layer 102 on the top of thermoelectric device 100. This may be done by filling a die with conductor or metal particles of first powdered conductor 101 followed by layering a first powdered semiconductor material 103 on top of first powdered conductor 101, and finally topping the stack with conductor or metal particles of the same type or a different type to the first powdered conductor 101 layer, in powdered conductor 102 layer, to complete the stack of materials. The conductor can include any known conductor, including metals. For instance, conductors 101, 102, or other subsequent conductors may include CoSi₂, MoCu, FeNiCr alloys or any of Fe, Ni, or Cr independently, or Co₂Si. These materials may then be consolidated together. The consolidation techniques can vary and may include, without limit, hot pressing, spark plasma sintering, cold isostatic pressing, hot isostatic pressing, cold pressing, and other consolidation methods. This technique generally leads to low contact resistance at the conductor-semiconductor interface, e.g., the interface of layers 101 and 103 or the interface of layers 102 and 103. Traditional methods, in contrast, often rely on metallization through electroplating or other deposition techniques, and frequently requiring dicing of the materials, polishing of the materials, or other costly, time consuming steps. Hence, this method can reduce process steps and can lead to better thermoelectric devices.

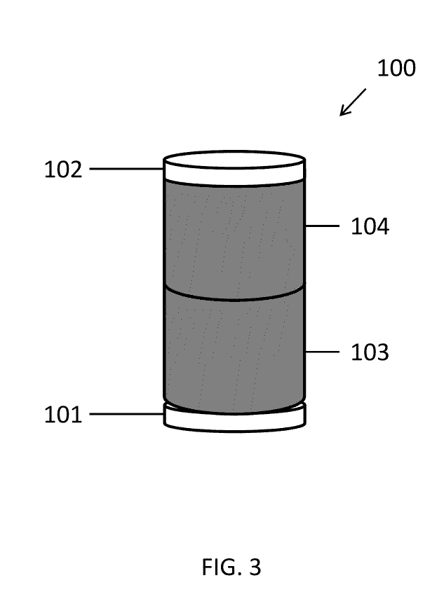

In another embodiment, two different semiconductor materials, as also illustrated in FIG. 3, may be consolidated together. In these embodiments, a second powdered semiconductor layer 104 may be added, which may be added between first powdered semiconductor layer 103 and one of the first powdered conductor 101 or the second powdered conductor 102. In some embodiments, first powdered semiconductor 103 and second powdered semiconductor layer 104 may comprise materials of different compositions, the same compositions with different initial grain sizes, or materials with different material properties. For instance, one semiconductor material may perform better at higher temperatures while another semiconductor material may perform better at lower temperatures. First powdered semiconductor layer 103, second powdered semiconductor 104, and any subsequent semiconductor layers may include, but are not limited to, Skutterudites, silicides, SeGe, BiTe, and Heusler alloys, such as half Heusler. These materials may be utilized together as separate layers and can be added as a powder to a die, utilizing the layering methods disclosed above, and subsequently consolidated. Multiple conductor layers and/or diffusion barriers can also be added to the die in such embodiments. In some embodiments, a diffusion barrier between the two different semiconductor materials may improve the performance of the resulting thermoelectric device 100.

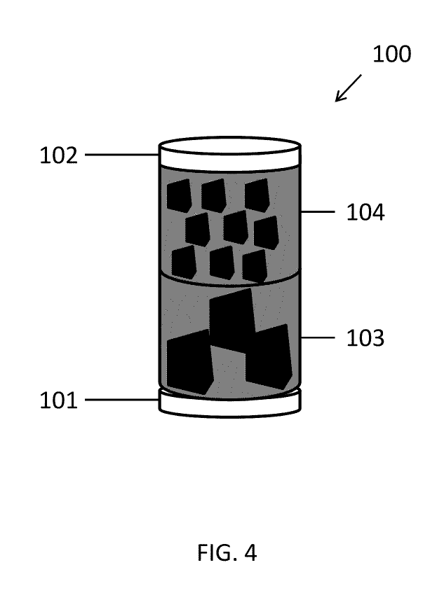

In another embodiment, as illustrated in FIG. 4, the particle size can be varied axially so that smaller particles are placed toward either side of thermoelectric device 100. For instance, first powdered semiconductor layer 103 may comprise a larger grain size and second powdered semiconductor layer 104 may comprise smaller initial grain sizes of the particles. It should be understood that any number of powdered semiconductor layers may be used, with any number of grain sizes. It should also be appreciated that the grain size may not be precise, but rather in a range, and the grain size can comprise a gradient across thermoelectric device 100. This size difference can change the phonon transport characteristics and hence the thermal conductivity of the resulting stacks. Multi-spectral phonon scattering can occur from the different grain sizes that are produced as a result of variations in the starting particle size.

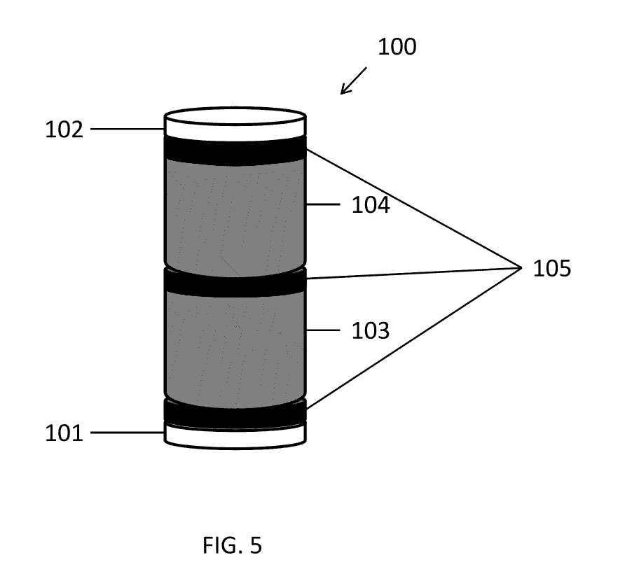

In another embodiment, illustrated in FIG. 5, at least one powdered diffusion barrier or thin foil diffusion barrier 105 can be added in the same manner as above to the stacked materials. As illustrated in FIG. 1, diffusion barriers 105 may be included between any number of layers, including different semiconductor materials and the conductor layers. These diffusion barriers 105 may be made of different materials, for example nickel, titanium, or zirconium, and can help to prevent atomic species from migrating into other regions of the device than the initial layer that they started in, where they may degrade the performance of thermoelectric device 100. Diffusion barriers 105 may vary in thickness from approximately 0.1 microns to approximately 200 microns. Constructing the diffusion barrier during the consolidation step can help to ensure that there is a good electrical contact between the regions on either side of the diffusion barrier, typically between conductor and semiconductor layers. This may also reduce processing steps that are typically required for adding a diffusion barrier to a material, including but not limited to cutting and polishing of the layers from the die.

In some embodiments, one or more dopants may be used in different axial regions. In one example, skutterudite materials can be doped with a variety of atomic species and each atomic species may have a slightly different effect on the electrical and thermal conductivity. The material can be designed or chosen in order to match the performance of the selected materials to the final temperature range of the thermoelectric element in operation. For example, a higher temperature side of the thermoelectric element can be doped with materials that scatter particle photon wavelengths while the region operating at a lower temperature can use a dopant that scatters other wavelengths. Heterogeneous materials used in a stack can result in improved performance over the same materials used as a homogenous mixture.

According to embodiments of the invention, following steps described herein, the die will produce a molded part with axially varying composition. The shape and dimensions of the parts are determined by the shape and dimensions of the die. For instance, a 3 mm diameter cylindrical hole in the die will produce a 3 mm diameter (approximately) cylindrical molded part. A rectangular hole will produce a rectangular molded part. A die can be designed or acquired in order to produce molded parts that are the required dimension and shape for direct use in a final application, such as a pillar used in a thermoelectric module consolidated to be the particular size and shape necessary for the module. This saves significant processing time as the pillars can be used directly without cutting, dicing, and polishing, as required in previous attempts.

In some embodiments, the materials may be consolidated into a cylindrical shape. This shape can increase the strength of the materials and reduce the chance of cracking within the consolidated material that has been seen in some previous rectangular shaped materials that have been used. Previously, rectangular shapes were more commonly used due to the fact that these materials were typically diced from a larger wafer. Straight-line cuts are the typical way of dicing so the thermoelectric elements were often inherently rectangular. Directly consolidating the disclosed materials into thermoelectric elements can negate the need for many dicing and polishing steps as well as adding strength and chip resistance, and allowing for spherical, cylindrical, or other specialized shapes of thermoelectric device 100 necessary for nearly any application. Even rectangular thermoelectric devices 100 made according to embodiments of the present invention are stronger than their previously diced counterparts, as the materials were consolidated in a single step and were never cut, which frequently causes weaknesses and splits in the material.

In yet another embodiment, rather than consolidating all of the layers at one time, one or more layers may be consolidated in advance. In these embodiments, one or more layers of material may be consolidated initially before adding further layers. These layers may be consolidated at higher temperatures, which can beneficially allow for consolidating or metalizing one or more materials into a thin pellet that can be used in any of the above disclosed consolidation embodiments as one or more layers, added as a solid rather than in a powdered form. In some instances, these pre-consolidated layers may be used as the top and the bottom layers, typically a conductor or metal layer, with one or more semiconductor and/or barrier layers added between them. The pre-consolidated layers may include conductors, metals, skutterudites, or semiconductor materials. Further, skutterudites may be utilized in any of the above disclosed layers. Any of the above disclosed layers may be pre-consolidated for similar use.

The foregoing description of various aspects of the invention has been presented for the purpose of illustration and description. It is not intended to be exhaustive or to limit the invention to the precise form disclosed, and obviously, many modifications and variations are possible. Such variations and modifications that may be apparent to one skilled in the art are intended to be included within the scope of the present invention as defined by the accompanying claims.

What is claimed:

1. A method of producing a thermoelectric device, the method comprising:
layering a first powdered conductor in a die;
layering a first powdered semiconductor material on the first powdered conductor layer;
layering a second powdered conductor in the die; and
consolidating each of the layers.

2. The method of claim 1, further comprising:
adding a second powdered semiconductor layer between the first powdered semiconductor layer and one of the first powdered conductor or the second powdered conductor.

3. The method of claim 2, wherein the first powdered semiconductor material and the second powdered semiconductor material comprise a different grain size from one another.

4. The method of claim 1, further comprising:
adding at least one powdered diffusion barrier or at least one thin foil diffusion barrier between at least two of the claimed layers.

5. The method of claim 1, wherein the powdered diffusion barrier or thin foil diffusion barrier includes titanium or zirconium.

6. The method of claim 1, wherein the first powdered conductor and the second powdered conductor comprise the same conductor.

7. The method of claim 1, wherein the first powdered conductor and the second powdered conductor comprise different conductors.

8. The method of claim 1, wherein at least one of the powdered layers is consolidated prior to being layered.

9. The method of claim 8, wherein at least a top layer and a bottom layer are consolidated prior to being layered.

10. A thermoelectric device produced by a method utilizing consolidation techniques, the method comprising:
layering a first powdered conductor in a die;
layering a first powdered semiconductor material on the first powdered conductor layer;
layering a second powdered conductor in the die; and
consolidating each of the layers.

11. The thermoelectric device of claim 10, further comprising:
adding a second powdered semiconductor layer between the first powdered semiconductor layer and one of the first powdered conductor or the second powdered conductor.

12. The thermoelectric device of claim 11, wherein the first powdered semiconductor material and the second powdered semiconductor material comprise a different grain size from one another.

13. The thermoelectric device of claim 10, further comprising:
adding at least one powdered diffusion barrier or at least one thin foil diffusion barrier between at least two of the claimed layers.

14. The thermoelectric device of claim 10, wherein the powdered diffusion barrier or thin foil diffusion barrier includes titanium or zirconium.

15. The thermoelectric device of claim 10, wherein the first powdered conductor and the second powdered conductor comprise the same conductor.

16. The thermoelectric device of claim 10, wherein the first powdered conductor and the second powdered conductor comprise different conductors.

17. The thermoelectric device of claim 10, wherein at least one of the powdered layers is consolidated prior to being layered.

18. The thermoelectric device of claim 17, wherein at least a top layer and a bottom layer are consolidated prior to being layered.
